(19) United States
(12) Patent Application Publication
(10) Pub. No.: US 2020/0411760 A1
(43) Pub. Date: Dec. 31, 2020

(54) VARIABLE RESISTANCE ELEMENT, METHOD FOR MANUFACTURING SAME, AND STORAGE DEVICE

(71) Applicant: FUJITSU LIMITED, Kawasaki-shi (JP)

(72) Inventors: Tomochika KURITA, Kawasaki (JP); Hideyuki NOSHIRO, Kawasaki (JP); Shintaro SATO, Atsugi (JP)

(73) Assignee: FUJITSU LIMITED, Kawasaki-shi (JP)

(21) Appl. No.: 17/017,746

(22) Filed: Sep. 11, 2020

Related U.S. Application Data
(63) Continuation of application No. PCT/JP2018/013706, filed on Mar. 30, 2018.

(51) Int. Cl. H01L 45/00; G11C 13/00

(52) U.S. Cl. CPC H01L 45/145; H01L 45/16; G11C 13/0069; G11C 13/004; G11C 13/0007

(57) ABSTRACT

A variable resistance element includes: a variable resistance layer that is able to occlude and release at least one type of ions, and changes a resistance of the variable resistance layer according to an amount of the at least one type of ions; an ion occluding/releasing layer that is able to occlude and release the at least one type of ions; and an ion conductive layer that conducts the at least one type of ions between the variable resistance layer and the ion occluding/releasing layer, wherein the variable resistance layer and the ion occluding/releasing layer are made of the same constituent elements.

### CROSS-REFERENCE TO RELATED APPLICATION

This application is a continuation application of International Application PCT/JP2018/013706 filed on Mar. 30, 2018 and designated the U.S., the entire contents of which are incorporated herein by reference.

### FIELD

The embodiment discussed herein is related to a variable resistance element, a method for manufacturing the same, and a storage device.

### BACKGROUND

Conventionally, there has been proposed a variable resistance element using a principle of a secondary battery that performs charging and discharging by movement of ions through an electrolyte layer between a positive electrode active material layer and a negative electrode active material layer and utilizing a configuration of the secondary battery.

Japanese National Publication of International Patent Application No. 2010-514150, International Publication Pamphlet No. MO 2016/186148, and Elliot J. Fuller et al. & quot; Li-Ion Synaptic Transistor for Low Power Analog Computing & quot; Advanced Materials 29(4), 1604310, 2017 are disclosed as related art.

### SUMMARY

According to an aspect of the embodiments, a variable resistance element includes: a variable resistance layer that is able to occlude and release at least one type of ions, and changes a resistance of the variable resistance layer according to an amount of the at least one type of ions; an ion occluding/releasing layer that is able to occlude and release the at least one type of ions; and an ion conductive layer that conducts the at least one type of ions between the variable resistance layer and the ion occluding/releasing layer, wherein the variable resistance layer and the ion occluding/releasing layer are made of the same constituent elements.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a configuration of a variable resistance element according to the present embodiment;

FIG. 2 is a graph for explaining an action and an effect of the variable resistance element according to the present embodiment;

FIG. 3 is a diagram illustrating a configuration of the variable resistance element according to the present embodiment and a storage device including the variable resistance element;

FIG. 4 is a perspective view illustrating a configuration of a device imitating a neural network with a crossbar structure;

FIG. 5 is a diagram illustrating a combination of values of x in a variable resistance layer of each variable resistance element of a neural network constituted using a variable resistance element of a first specific example of the present embodiment;

FIG. 6 is a graph illustrating a relationship between a combination of values of x and an output current in a variable resistance layer of each variable resistance element of the neural network constituted using the variable resistance element of the first specific example of the present embodiment; and

FIG. 7 is a diagram illustrating a combination of values of x in a variable resistance layer of each variable resistance element of a neural network constituted using a variable resistance element of a second specific example of the present embodiment.

### DESCRIPTION OF EMBODIMENTS

By the way, in a case where the above-described configuration of the secondary battery is applied to a variable resistance element included in a storage device, for example, it is conceivable that the positive electrode active material layer is used as a variable resistance layer that can occlude and release ions and changes its resistance according to the amount (concentration) of ions, the electrolyte layer is used as an ion conductive layer that conducts ions, and the negative electrode active material layer is used as an on occluding/releasing layer that can occlude and release ions.

In this case, the amount (concentration) of ions in the variable resistance layer changes by movement of ions through the ion conductive layer between the variable resistance layer and the ion occluding/releasing layer, and the resistance of the variable resistance layer changes according to the change in the amount (concentration) of ion. Therefore, a function as a variable resistance element may be achieved.

However, it has been found that if materials used for the variable resistance layer and the ion occluding/releasing layer are not properly selected, a voltage applied at the time of writing is large, and electric energy required at the time of writing is large.

A voltage applied at the time of writing and electric energy required at the time of writing may be reduced.

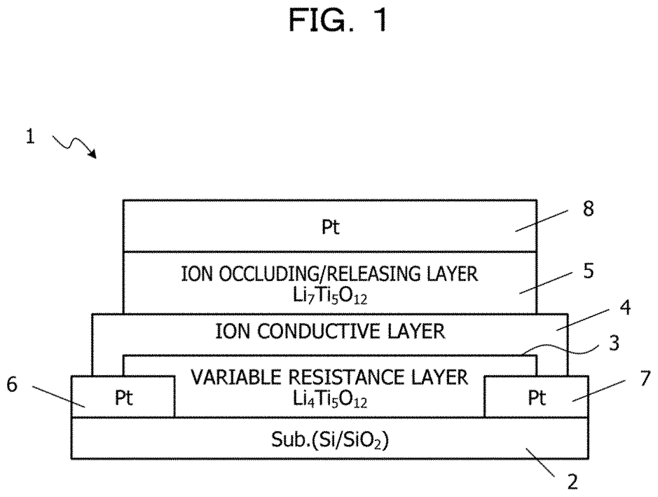

Hereinafter, a variable resistance element, a method for manufacturing the same, and a storage device according to an embodiment will be described with reference to FIGS. 1 to 7.

The variable resistance element according to the present embodiment is a variable resistance element to which a configuration of a secondary battery that performs charging and discharging by movement of ions through an electrolyte layer (solid electrolyte layer) between a positive electrode active material layer and a negative electrode active material layer is applied. Note that the secondary battery is also referred to as a solid-state secondary battery, an all-solid-state secondary battery, a solid-state battery, an all-solid-state battery, or an ion battery.

That is, for example, the variable resistance element according to the present embodiment includes a variable resistance layer that can occlude and release at least one type of ions and changes its resistance according to the amount (concentration) of the at least one type of ions as a layer corresponding to the positive electrode active material layer of the secondary battery, includes an ion conductive layer that conducts the at least one type of ions as a layer corresponding to the electrolyte layer (solid electrolyte layer), and includes an ion occluding/releasing layer that can occlude and release the at least one type of ions as a layer corresponding to the negative electrode active material layer.

Therefore, as illustrated in FIG. 1, a variable resistance element 1 of the present embodiment includes, on a substrate 2, a variable resistance layer 3 that can occlude and release at least one type of ions and changes its resistance according to the amount (concentration) of the at least one type of ions, an ion occluding/releasing layer 5 that can occlude and release the at least one type of ions, and an ion conductive layer 4 that conducts the at least one type of ions between the variable resistance layer 3 and the ion occluding/releasing layer 5.

Here, the variable resistance layer 3 is made of a material that can occlude and release the at least one type of ions, and changes its resistance according to the amount (concentration) of the at least one type of ions. Furthermore, the ion conductive layer 4 is made of a material that conducts the at least one type of ions. Furthermore, the ion occluding/releasing layer 5 is made of a material that can occlude and release the at least one type of ions.

In the present embodiment, the variable resistance layer 3 is a positive electrode active material layer made of a positive electrode active material used in an ion battery, the ion conductive layer 4 is a solid electrolyte layer made of a solid electrolyte used in the ion battery, and the ion occluding/releasing layer 5 is a negative electrode active material layer made of a negative electrode active material used in the ion battery.

In this case, the amount (concentration) of ions in the variable resistance layer 3 changes by movement of ions through the ion conductive layer 4 between the variable resistance layer 3 and the ion occluding/releasing layer 5, and the resistance of the variable resistance layer 3 changes according to the change in the amount (concentration) of ion. Therefore, a function as the variable resistance element 1 may be achieved.

Note that here, the ion conductive layer 4 is an ion conductive layer that conducts the at least one type of ions and does not conduct electrons.

Note that ions that move between the variable resistance layer 3 and the ion occluding/releasing layer 5 through the ion conductive layer 4 are also referred to as conductive ions. Furthermore, the ion occluding/releasing layer 5 is also referred to as an ion supply layer.

Furthermore, the amount (concentration) of ions in the variable resistance layer 3 can be continuously changed, and resistance of the variable resistance layer 3 can be continuously changed. Therefore, a multi-valued variable resistance element that can store many resistance values may also be achieved.

In the present embodiment, the variable resistance element 1 has a structure in which the variable resistance layer 3, the ion conductive layer 4, and the ion occluding/releasing layer 5 are stacked in this order, and the ion conductive layer 4 is sandwiched between the variable resistance layer 3 and the ion occluding/releasing layer 5, and can electrochemically control the concentration of conductive ions in the variable resistance layer 3 to control the resistance of the variable resistance layer 3.

In particular, in the present embodiment, the variable resistance layer 3 and the ion occluding/releasing layer 5 are made of the same constituent elements. That is, for example, for the variable resistance layer 3 and the ion occluding/releasing layer 5, a material made of the same constituent elements, in other words, the same material is used.

For example, in a case where the conductive ions are Li ions, Li₄Ti₅O₁₂ is used for the variable resistance layer 3, and Li₇Ti₅O₂ is used for the ion occluding/releasing layer 5, the variable resistance layer 3 and the ion occluding/releasing layer 5 are made of the same constituent elements. In this case, the variable resistance layer 3 and the ion occluding/releasing layer 5 each have a composition represented by the same composition formula, Li₄₊ₓTi₅O₁₂ (0≤x≤3).

In this case, the variable resistance layer 3 and the ion occluding/releasing layer 5 only need to have the same composition ratio of elements other than the element to be used as the conductive ions. In this case, it can be said that the variable resistance layer 3 and the ion occluding/releasing layer 5 are made of the same material.

For example, in a case where the conductive ions are Li ions, Li₄Ti₅O₁₂ is used for the variable resistance layer 3, and Li₇Ti₅O₁₂ is used for the ion occluding/releasing layer 5, the composition ratio of elements other than Li is Ti:O=5:12 in both of Li₄Ti₅O₁₂ and Li₇Ti₅O₁₂. Therefore, it can be said that the variable resistance layer 3 and the ion occluding/releasing layer 5 are made of the same material.

In this case, the variable resistance layer 3 and the ion occluding/releasing layer 5 may have different composition ratios of the element to be used as the conductive ions, or may have the same composition ratio of the element to be used as the conductive ions.

That is, the variable resistance layer 3 and the ion occluding/releasing layer 5 may have different amounts (concentrations) of the element to be used as the conductive ions, or may have the same amount (concentration) of the element to be used as the conductive ions.

As described above, the same material means that the variable resistance layer 3 and the ion occluding/releasing layer 5 only need to have the same composition ratio of elements other than the element to be used as the conductive ions.

Note that the content of the element to be used as the conductive ions in the variable resistance layer 3 and the ion occluding/releasing layer 5 changes depending on a resistance value of the variable resistance layer 3.

By thus constituting the variable resistance layer 3 and the ion occluding/releasing layer 5 with the same material, it is possible to reduce required energy at the time of writing (at the time of rewriting) a resistance value (weight value; memory value; data; information).

That is, for example, by constituting the variable resistance layer 3 and the ion occluding/releasing layer 5 with the same material, it is possible to reduce a potential difference between these layers. Therefore, it is possible to reduce a voltage required for changing the amount of conductive ions (composition of the element to be used as the conductive ions) in the variable resistance layer 3. Therefore, a voltage applied at the time of writing can be reduced, and electric energy required at the time of writing can be reduced.

Here, a case where the conductive ions are Li ions, Li₄Ti₅O₁₂ is used for the variable resistance layer 3, and Li₇Ti₅O₁₂ is used for the ion occluding/releasing layer 5 will be described as an example.

Li₄Ti₅O₁₂ can cause a lithium insertion/elimination reaction as illustrated in the following reaction formula.

Li₄Ti₅O₁₂+3Li⁺+3e⇔Li₇Ti₅O₁₂

This insertion/elimination involves redox of Ti^{4+/3+}, and the potential of Ti^{4+/3+} is about 1.5 V (vs. Li⁺/Li). In other words, for example, when the redox potential of lithium is 0 V, the redox potential of Ti^{4+/3+} is 1.5 V.

Here, in the case where Li₄Ti₅O₁₂ is used for the variable resistance layer 3 and Li₇Ti₅O₁₂ is used for the ion occluding/releasing layer 5, the variable resistance element 1 can be regarded as an all-solid-state battery including the variable resistance layer 3 as a layer corresponding to the positive electrode active material layer, and including the ion occluding/releasing layer 5 as a layer corresponding to the negative electrode active material layer. Therefore, a voltage of the all-solid-state battery will be considered.

If it is assumed that the substance amount of Li₄Ti₅O₁₂ in the variable resistance layer 3 and the substance amount of Li₇Ti₅O₁₂ in the ion occluding/releasing layer 5 are equal, the compositions of the variable resistance layer 3 and the ion occluding/releasing layer 5 in a charging/discharging process can be represented using x (0≤x≤3) by Li₄₊ₓTi₅O₁₂ and Li₇₋ₓTi₅O₁₂, respectively.

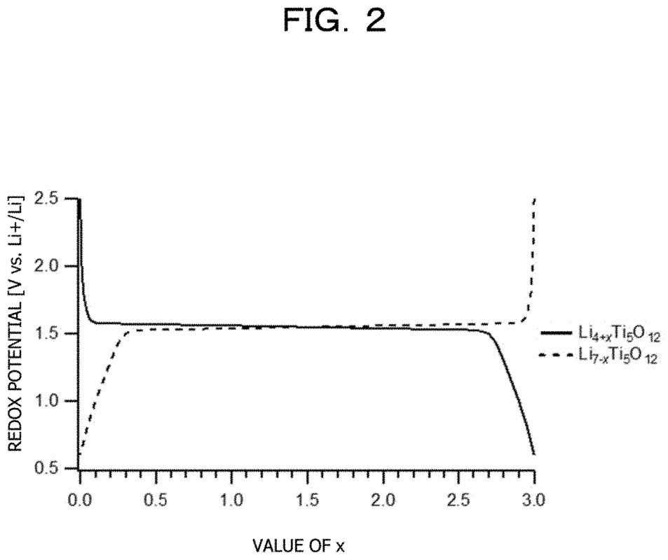

Here, FIG. 2 illustrates x value dependence of the potential (vs. Li⁺/Li) of each of the variable resistance layer 3 using Li₄₊ₓTi₅O₁₂ and the ion occluding/releasing layer 5 using Li₇₋ₓTi₅O₁₂.

As illustrated in FIG. 2, when a value of x is in a range of 0.3 to 2.7, a potential difference between the variable resistance layer 3 using Li₄₊ₓTi₅O₁₂ and the ion occluding/releasing layer 5 using Li₇₋ₓTi₅O₁₂ is less than about 0.1 V (<0.1 V).

This means that a voltage required for changing a value of x of the variable resistance layer 3 using Li₄₊ₓTi₅O₁₂ is less than about 0.1 V.

As described above, by constituting the variable resistance layer 3 and the ion occluding/releasing layer 5 with the same material, a potential difference between these layers can be reduced. Therefore, a voltage applied at the time of writing can be reduced, and electric energy required at the time of writing can be reduced.

By the way, the conductive ions are preferably any one of Li ions, Zn ions, Na ions, K ions, Mg ions, Al ions, Ag ions, and Cu ions.

Among these ions, in a case where the conductive ions are Li ions (lithium ions), the variable resistance layer 3 and the ion occluding/releasing layer 5 are made of, for example, a material such as Li₄₊ₓTi₅O₁₂ (0≤x≤3), Li₃₊ₓV₂(PO₄)₃ (−2≤x≤2), Li₃₊ₓFe₂(PO₄)₃ (0≤x≤2), Li₁₊ₓVP₂O₇ (−1≤x≤1), Li₁₊ₓFeP₂O₇ (0≤x≤1), LiₓMnO₂ (0≤x≤1), or LiₓTiO₂ (0≤x≤1), and only need to be made of the same constituent elements. Furthermore, the ion conductive layer 4 only needs to be made of, for example, a material such as LiPON, Li₉Al₃(P₂O₇)₃(PO₄)₂, Li_{3z}La_{2/3-z}TiO₃ (0≤z≤⅙), or Li₇La₃Zr₂O₁₂.

Note that there is no particular limitation on a crystal state (crystalline or amorphous) of the variable resistance layer 3, the ion conductive layer 4, and the ion occluding/releasing layer 5.

In particular, it is most preferable to use Li₄₊ₓTi₅O₁₂ (0≤x≤3), having a high average electron transfer conductivity for the variable resistance layer 3 and the ion occluding/releasing layer 5.

For example, preferably, the variable resistance layer 3 and the ion occluding/releasing layer 5 are made of the same constituent elements and each have a composition represented by the same composition formula, Li₄₊ₓTi₅O₁₂ (0≤x≤3). That is, for example, it is preferable to use a material (same material) made of the same constituent elements and represented by the same composition formula, Li₄₊ₓTi₅O₁₂ (0≤x≤3) for the variable resistance layer 3 and the ion occluding/releasing layer 5.

In particular, at least one of the variable resistance layer 3 and the ion occluding/releasing layer 5 is preferably adjusted such that a value of x satisfies 0<x≤3.

That is, for example, in an initial state, at least one of the variable resistance layer 3 and the ion occluding/releasing layer 5 having a composition represented by Li₄₊ₓTi₅O₁₂ (x=0) is preferably adjusted such that a value of x satisfies 0<x≤3.

A reason thereof is as follows.

That is, for example, in a case where a material represented by Li₄₊ₓTi₅O₁₂ (0≤x≤3) is used for the variable resistance layer 3 and the ion occluding/releasing layer 5, a state of x=0 is a thermodynamically stable state. Therefore, in an initial state, the variable resistance layer 3 and the ion occluding/releasing layer 5 are both formed in the state of x=0.

Meanwhile, the material represented by Li₄₊ₓTi₅O₁₂ (0≤x≤3) is not able to be in a state of x<0. Therefore, when both the variable resistance layer 3 and the ion occluding/releasing layer 5 are in the state of x=0, Li ions are not able to be exchanged between the variable resistance layer 3 and the ion occluding/releasing layer 5.

Therefore, in order to be able to exchange Li ions between the variable resistance layer 3 and the ion occluding/releasing layer 5, it is preferable to perform adjustment chemically such that a value of x of at least one of the variable resistance layer 3 and the ion occluding/releasing layer 5 satisfies 0<x≤3.

Here, the adjustment can be performed by the following method.

A metallic lithium film is formed on the formed Li₄Ti₅O₁₂ film.

Next, the Li₄Ti₅O₁₂ film and the metallic lithium film are allowed to react with each other according to the following scheme.

Li₄Ti₅O₁₂+yLi→Li_{4+y}Ti₅O₁₂

Note that the reaction proceeds only by leaving the Li₄Ti₅O₁₂ film and the metallic lithium film at room temperature, but can also be accelerated by placing the Li₄Ti₅O₁₂ film and the metallic lithium film in a high temperature state (for example, about 30° C. to about 80° C.).

In this way, in a case where adjustment is performed such that a value of x of at least one of the variable resistance layer 3 and the ion occluding/releasing layer 5 satisfies 0<x≤3, for example, the variable resistance layer 3 only needs to be made of Li₄Ti₅O₁₂ without the above adjustment, and the ion occluding/releasing layer 5 only needs to be made of Li₇Ti₅O₁₂ by the above adjustment. Furthermore, for example, the variable resistance layer 3 may be made of Li₅Ti₅O₁₂ by the above adjustment, and the ion occluding/releasing layer 5 may be made of Li₅Ti₅O₁₂ by the above adjustment. Furthermore, for example, the variable resistance layer 3 may be made of Li₇Ti₅O₁₂ by the above adjustment, and the ion occluding/releasing layer may be made of Li₄Ti₅O₁₂ without the above adjustment.

As described above, as a result of the above adjustment, the variable resistance layer 3 and the ion occluding/releasing layer 5 may have the same value of x or different values of x.

Here, the case where the variable resistance layer 3 and the ion occluding/releasing layer 5 have the same value of x means that the variable resistance layer 3 and the ion occluding/releasing layer 5 have the same composition ratio of the element to be used as the conductive ions. Furthermore, the case where the variable resistance layer 3 and the ion occluding/releasing layer 5 have different values of x means that the variable resistance layer 3 and the ion occluding/releasing layer 5 have different composition ratios of the element to be used as the conductive ions. In either case, the variable resistance layer 3 and the ion occluding/releasing layer 5 have the same composition ratio of elements other than the element to be used as the conductive ions.

Note that here, the case where a material represented by Li₄₊ₓTi₅O₁₂ (0≤x≤3) is used for the variable resistance layer 3 and the ion occluding/releasing layer 5 is described as an example, but the present embodiment is not limited thereto. For example, the same applies to a case where a material represented by Li₃₊ₓFe₂(PO₄)₃ (0≤x≤2), Li₁₊ₓFeP₂O (0≤x≤1), LiₓMnO₂ (0≤x≤1), or LiₓTiO₂ (0≤x≤1) is used.

That is, for example, in a case where a material represented by Li₄₊ₓTi₅O₁₂ (0≤x≤3), Li₃₊ₓFe₂(PO₄)₃ (0≤x≤2), Li₁₊ₓFeP₂O₇ (0≤x≤1), LiₓMnO₂ (0≤x≤1), or LiₓTiO₂ (0≤x≤1) is used for the variable resistance layer 3 and the ion occluding/releasing layer 5, a state of x=0 is a thermodynamically stable state. Therefore, in an initial state, the variable resistance layer 3 and the ion occluding/releasing layer 5 are both formed in the state of x=0. Meanwhile, these materials are not able to be in a state of x<0. Therefore, when both the variable resistance layer 3 and the ion occluding/releasing layer 5 are in the state of x=0, Li ions are not able to be exchanged between the variable resistance layer 3 and the ion occluding/releasing layer 5. Therefore, in order to be able to exchange Li ions between the variable resistance layer 3 and the ion occluding/releasing layer 5, it is preferable to chemically adjust a value of x of at least one of the variable resistance layer 3 and the ion occluding/releasing layer 5.

Therefore, the variable resistance layer 3 and the ion occluding/releasing layer 5 may have the same value of x or different values of x. Then, the case where the variable resistance layer 3 and the ion occluding/releasing layer 5 have the same value of x means that the variable resistance layer 3 and the ion occluding/releasing layer 5 have the same composition ratio of the element to be used as the conductive ions. Furthermore, the case where the variable resistance layer 3 and the ion occluding/releasing layer 5 have different values of x means that the variable resistance layer 3 and the ion occluding/releasing layer 5 have different composition ratios of the element to be used as the conductive ions. In either case, the variable resistance layer 3 and the ion occluding/releasing layer 5 have the same composition ratio of elements other than the element to be used as the conductive ions.

Meanwhile, in a case where a material represented by Li₃₊ₓV₂(PO₄)₃ (−2≤x≤2) or Li₁₊ₓVP₂O₇ (−1≤x≤1) is used for the variable resistance layer 3 and the ion occluding/releasing layer 5, these materials can be in a state of x<0. Therefore, it is not needed to chemically adjust a value of x as described above. In this respect, these materials are easily manufactured. Then, in a case where the adjustment is not performed, the variable resistance layer 3 and the ion occluding/releasing layer 5 have the same value of x. The variable resistance layer 3 and the ion occluding/releasing layer 5 have the same composition ratio of the element to be used as the conductive ions. Also in this case, the variable resistance layer 3 and the ion occluding/releasing layer 5 have the same composition ratio of elements other than the element to be used as the conductive ions.

Furthermore, in a case where the conductive ions are Zn ions (zinc ions), the variable resistance layer 3 and the ion occluding/releasing layer 5 are made of, for example, a material such as ZnₓMnO₂ (0≤x≤0.5), ZnₓTiO₂ (0≤x≤0.5), ZnₓV₂O₅ (0≤x≤1.5), or ZnₓLiV₃O₈ (0≤x≤1.5), and only need to be made of the same constituent elements. Furthermore, the ion conductive layer 4 only needs to be made of, for example, a material such as ZnZr₄(PO₄)₆ or Zn_{1.5z}La_{2/3-z}TiO₃ (0≤z≤⅙).

For example, preferably, the variable resistance layer 3 and the ion occluding/releasing layer 5 are made of the same constituent elements and have a composition represented by the same composition formula, ZnₓMnO₂ (0≤x≤0.5). That is, for example, it is preferable to use a material (same material) made of the same constituent elements and represented by the same composition formula, ZnₓMnO₂ (0≤x≤0.5) for the variable resistance layer 3 and the ion occluding/releasing layer 5.

In particular, at least one of the variable resistance layer 3 and the ion occluding/releasing layer 5 is preferably adjusted such that a value of x satisfies 0<x≤0.5.

That is, for example, in an initial state, at least one of the variable resistance layer 3 and the ion occluding/releasing layer 5 having a composition represented by ZnₓMnO₂ (x=0) is preferably adjusted such that a value of x satisfies 0<x≤0.5.

A reason thereof is as follows.

That is, for example, in a case where a material represented by ZnₓMnO₂ (0·x≤0.5) is used for the variable resistance layer 3 and the ion occluding/releasing layer 5, a state of x=0 is a thermodynamically stable state. Therefore, in an initial state, the variable resistance layer 3 and the ion occluding/releasing layer 5 are both formed in the state of x=0.

Meanwhile, the material represented by ZnₓMnO₂ (0≤x≤0.5) is not able to be in a state of x<0. Therefore, when both the variable resistance layer 3 and the ion occluding/releasing layer 5 are in the state of x=0, Zn ions are not able to be exchanged between the variable resistance layer 3 and the ion occluding/releasing layer 5.

Therefore, in order to be able to exchange Zn ions between the variable resistance layer 3 and the ion occluding/releasing layer 5, it is preferable to perform adjustment chemically such that a value of x of at least one of the variable resistance layer 3 and the ion occluding/releasing layer 5 satisfies 0<x≤0.5.

Here, the adjustment can be performed by the following method.

A metallic zinc film is formed on the formed MnO₂ film.

Next, the MnO₂ film and the metallic zinc film are allowed to react with each other according to the following scheme.

MnO₂+yZn→Zn_{y}MnO₂

Note that the reaction proceeds only by leaving the MnO₂ film and the metallic zinc film at room temperature, but can also be accelerated by placing the MnO₂ film and the metallic zinc film in a high temperature state (for example, about 30° C. to about 80° C.).

In this way, in a case where adjustment is performed such that a value of x of at least one of the variable resistance layer 3 and the ion occluding/releasing layer 5 satisfies 0≤x≤0.5, for example, the variable resistance layer 3 only needs to be made of MnO₂ without the above adjustment, and the ion occluding/releasing layer 5 only needs to be made of Zn_{0.5}MnO₂ by the above adjustment. Furthermore, for example, the variable resistance layer 3 may be made of Zn_{0.3}MnO₂ by the above adjustment, and the ion occluding/releasing layer 5 may be made of Zn_{0.3}MnO₂ by the above adjustment. Furthermore, for example, the variable resistance layer 3 may be made of Zn_{0.5}MnO₂ by the above adjustment, and the ion occluding/releasing layer 5 may be made of MnO₂ without the above adjustment.

As described above, as a result of the above adjustment, the variable resistance layer 3 and the ion occluding/releasing layer 5 may have the same value of x or different values of x.

Here, the case where the variable resistance layer 3 and the ion occluding/releasing layer 5 have the same value of x means that the variable resistance layer 3 and the ion occluding/releasing layer 5 have the same composition ratio of the element to be used as the conductive ions. Furthermore, the case where the variable resistance layer 3 and the ion occluding/releasing layer 5 have different values of x means that the variable resistance layer 3 and the ion occluding/releasing layer 5 have different composition ratios of the element to be used as the conductive ions. In either case, the variable resistance layer 3 and the ion occluding/releasing layer 5 have the same composition ratio of elements other than the element to be used as the conductive ions.

Note that here, the case where a material represented by ZnₓMnO₂ is used for the variable resistance layer 3 and the on occluding/releasing layer 5 is described as an example, but the present embodiment is not limited thereto. For example, the same applies to a case where a material represented by ZnₓTiO₂ (0≤x≤0.5) is used.

That is, for example, in a case where a material represented by ZnₓTiO₂ (0≤x≤0.5) is used for the variable resistance layer 3 and the ion occluding/releasing layer 5, a state of x=0 is a thermodynamically stable state. Therefore, in an initial state, the variable resistance layer 3 and the ion occluding/releasing layer 5 are both formed in the state of x=0. Meanwhile, these materials are not able to be in a state of x<0. Therefore, when both the variable resistance layer 3 and the ion occluding/releasing layer 5 are in the state of x=0, Zn ions are not able to be exchanged between the variable resistance layer 3 and the ion occluding/releasing layer 5. Therefore, in order to be able to exchange Zn ions between the variable resistance layer 3 and the ion occluding/releasing layer 5, it is preferable to chemically adjust a value of x of at least one of the variable resistance layer 3 and the ion occluding/releasing layer 5.

Therefore, the variable resistance layer 3 and the ion occluding/releasing layer 5 may have the same value of x or different values of x. Then, the case where the variable resistance layer 3 and the ion occluding/releasing layer 5 have the same value of x means that the variable resistance layer 3 and the ion occluding/releasing layer 5 have the same composition ratio of the element to be used as the conductive ions. Furthermore, the case where the variable resistance layer 3 and the ion occluding/releasing layer 5 have different values of x means that the variable resistance layer 3 and the ion occluding/releasing layer 5 have different composition ratios of the element to be used as the conductive ions. In either case, the variable resistance layer 3 and the ion occluding/releasing layer 5 have the same composition ratio of elements other than the element to be used as the conductive ions.

Note that here, the case where the conductive ions are Li ions or Zn ions has been described, but the same applies to a case where the conductive ions are other ions.

Here, in a case where the conductive ions are other ions, the following materials only need to be used for the variable resistance layer 3, the ion occluding/releasing layer 5, and the ion conductive layer 4.

That is, for example, in a case where the conductive ions are Na ions (sodium ions), the variable resistance layer 3 and the ion occluding/releasing layer 5 are made of, for example, a material such as Na₁₊ₓTi₂(PO₄) (0≤x≤2), Na₂₊ₓTi₃O₇ (0≤x≤3), Na₃₊ₓV₂(PO₄)₃ (−2≤x≤2), Na_{3-z}V_{2-z}Zr_{z}(PO₄), NaₓMnO₂ (0≤x≤1), or NaₓTiO₂ (0≤x≤1), and only need to be made of the same constituent elements. Furthermore, the ion conductive layer 4 only needs to be made of, for example, a material such as Na₃PO₄, Na₃Zr₂(SiO₄)₂PO₄, Na_{3.3}Sc_{0.3}Zr_{1.7}(SiO₄)₂(PO₄), or Na⁺-β″-Al₂O₃.

Furthermore, in a case where the conductive ions are K ions (potassium ions), the variable resistance layer 3 and the on occluding/releasing layer 5 are made of, for example, a material such as KₓMnO₂ (0≤x≤1), K₃₊ₓV₂(PO₄)₃ (−2≤×≤2), or KₓV₂O₅ (0≤x≤3), and only need to be made of the same constituent elements. Furthermore, the ion conductive layer 4 only needs to be made of, for example, a material such as K⁺-β″-Al₂O₃.

Furthermore, in a case where the conductive ions are Mg ions (magnesium ions), the variable resistance layer 3 and the ion occluding/releasing layer 5 are made of, for example, a material such as MgₓV₂O₅ (0≤x≤1.5), MgₓMnO₂ (0≤x≤0.5), or Mg_{0.5+x}Ti₂(PO₄)₃ (0≤x≤1), and only need to be made of the same constituent elements. Furthermore, the ion conductive layer 4 only needs to be made of, for example, a material such as MgHf(WO₄)₃, Mg_{0.5}Zr₂(PO₄)₃, or Mg_{0.35}(Zr_{0.85}Nb_{0.15})₂(PO₄)₃Zn_{1.5z}La_{2/3-z}TiO₃ (0≤z≤⅙).

Furthermore, in a case where the conductive ions are Al ions (aluminum ions), the variable resistance layer 3 and the ion occluding/releasing layer 5 are made of, for example, a material such as AlₓV₂O₅ (0≤x≤1) or AlₓMnO₂ (0≤x≤⅓), and only need to be made of the same constituent elements. Furthermore, the ion conductive layer 4 only needs to be made of, for example, a material such as Al₂(WO₄)₃.

Furthermore, in a case where the conductive ions are Ag ions (silver ions), the variable resistance layer 3 and the ion occluding/releasing layer 5 are made of, for example, a material such as AgₓMoO₃ (0≤x≤1), AgₓMoS₂ (0≤x≤1), AgₓTiS₂ (0≤x≤1), AgₓBi₂Se₃ (0≤x≤1), or AgₓTiSe₂ (0≤x≤1), and only need to be made of the same constituent elements. Furthermore, the ion conductive layer 4 only needs to be made of, for example, a material such as AgI—Ag₂O—P₂O₅.

Furthermore, in a case where the conductive ions are Cu ions (copper ions), the variable resistance layer 3 and the ion occluding/releasing layer 5 are made of, for example, a material such as CuₓMoO₃ (0≤x≤1), CuₓMoS₂ (0≤x≤1), CuₓTiS₂ (0≤x≤1), CuₓBi₂Se₃ (0≤x≤1), or CuₓTiSe₂ (0≤x≤1), and only need to be made of the same constituent elements. Furthermore, the ion conductive layer 4 only needs to be made of, for example, a material such as CuI—Cu₂O—P₂O₅.

Next, a method for manufacturing a variable resistance element according to the present embodiment will be described.

The method for manufacturing a variable resistance element according to the present embodiment includes a step of forming the variable resistance layer 3 that can occlude and release at least one type of ions, and changes its resistance according to the amount of the at least one type of ions, a step of forming the ion occluding/releasing layer 5 that can occlude and release the at least one type of ions, and a step of forming the ion conductive layer 4 that conducts the at least one type of ions between the variable resistance layer 3 and the ion occluding/releasing layer 5.

Then, in the step of forming the variable resistance layer 3 and the step of forming the ion occluding/releasing layer 5, the variable resistance layer 3 and the ion occluding/releasing layer 5 made of the same constituent elements are formed, respectively.

By the way, as a specific configuration example, for example, as illustrated in FIG. 1, for example, on the substrate 2 such as a Si substrate having a SiO₂ film (silicon oxide film; insulating film), it is only needed to stack the variable resistance layer 3 having, for example, a composition represented by Li₄₊ₓTi₅O₁₂ (x=0), in other words, Li₄Ti₅O₁₂, the ion conductive layer 4 made of, for example, LiPON, and the ion occluding/releasing layer 5 having, for example, a composition represented by Li₄₊ₓTi₅O₁₂ (x=3), in other words, Li₇Ti₅O₁₂ in this order, to dispose a first electrode 6 and a second electrode 7 made of, for example, Pt on both sides of the variable resistance layer 3, and to dispose a third electrode 8 made of, for example, Pt on the ion occluding/releasing layer 5.

In this case, the first electrode 6 and the second electrode 7 are used for reading out a resistance value (weight value; memory value; data; information). Therefore, the first electrode 6 and the second electrode 7 are also referred to as a first read electrode and a second read electrode, or an input electrode and an output electrode, respectively.

Furthermore, at least one of the first electrode 6 and the second electrode 7 (here, the second electrode 7) and the third electrode 8 are used for writing (rewriting) a resistance value (weight value; memory value; data; information). Therefore, at least one of the first electrode 6 and the second electrode 7 (here, the second electrode 7) and the third electrode 8 are also referred to as a first write electrode and a second write electrode, or a first extraction electrode and a second extraction electrode, respectively.

The variable resistance element having such a configuration can be manufactured as follows.

For example, on the substrate 2 such as a Si substrate having a SiO₂ film, the first electrode 6, the second electrode 7, the variable resistance layer 3, the ion conductive layer 4, and the ion occluding/releasing layer 5 are formed.

That is, for example, on the substrate 2 such as a SI substrate having a SiO₂ film, the first electrode 6, the second electrode 7, the variable resistance layer 3, the ion conductive layer 4, and the ion occluding/releasing layer 5 are formed such that the first electrode 6 and the second electrode 7 are electrically connected to the variable resistance layer 3, and the variable resistance layer 3, the ion conductive layer 4, and the ion occluding/releasing layer 5 are stacked in this order.

Then, the third electrode 8 is formed on the on occluding/releasing layer 5. That is, for example, the third electrode 8 is formed on the ion occluding/releasing layer 5 so as to be electrically connected to the ion occluding/releasing layer 5.

Note that here, at least one of the first electrode 6 and the second electrode 7 (here, the second electrode 7) serves as a read electrode and a write electrode, but the present embodiment is not limited thereto. The first electrode 6 and the second electrode 7 may be used as read electrodes, and a fourth electrode may be disposed as a write electrode separately from the first electrode 6 and the second electrode 7. In this case, the fourth electrode only needs to be disposed on the opposite side of the third electrode 8 with the variable resistance layer 3, the ion conductive layer 4, and the ion occluding/releasing layer 5 interposed therebetween so as to be electrically connected to the variable resistance layer 3.

Furthermore, the order of stacking the layers, the positions where the electrodes are disposed, the number of the electrodes, and the like are not limited to the above-described configuration example. For example, the ion occluding/releasing layer, the ion conductive layer, and the variable resistance layer may be stacked in this order, the electrodes may be disposed at other positions, or the number of the electrodes may be increased or decreased.

By the way, the variable resistance element 1 having such a configuration as described above can write (rewrite) and read out (read) a resistance value (weight value; memory value; data; information) as follows.

At the time of writing (at the time of rewriting) a resistance value (weight value), only by applying a voltage (electric energy) of, for example, less than about 0.1 V between at least one of the first electrode 6 and the second electrode 7 (here, the second electrode 7) electrically connected to each of the variable resistance layer 3 and the ion occluding/releasing layer 5, and the third electrode 8, the amount (concentration) of the conductive ions in the variable resistance layer 3 can be adjusted, a resistance value (weight value) of the variable resistance layer 3 can be changed so as to be a target resistance value (weight value), and the resistance value (weight value) can be written (rewritten) in the variable resistance layer 3.

At the time of reading out (reading) a resistance value (weight value), between the first electrode 6 and the second electrode 7 electrically connected to both sides of the variable resistance layer 3, a voltage of, for example, about 1 mV to about 100 mV is applied, a current value flowing from the first electrode 6 on an input side to the second electrode 7 on an output side through the variable resistance layer 3 is monitored, and a resistance value (weight value) of the variable resistance layer 3 can be read out based on this monitored current value.

Here, when an application voltage (input voltage) is represented by Vᵢₙₚᵤₜ and a resistance value of the variable resistance layer is represented by R, a monitored current value Iₒᵤₜₚᵤₜ can be expressed by the following formula.

Iₒᵤₜₚᵤₜ=Vᵢₙₚᵤₜ/R

Furthermore, a neural network for, for example, machine learning can be manufactured using the variable resistance element 1 having such a configuration.

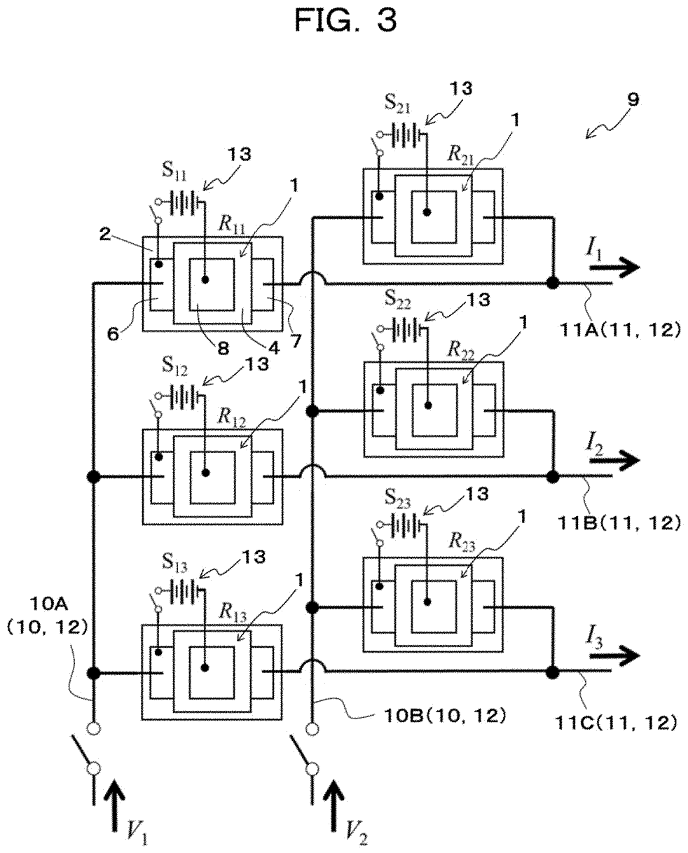

For example, as illustrated in FIG. 3, a neural network 9 can include m (here, m=2) input wires 10 (here, 10A and 10B), n (here, n=3) output wires 11 (here, 11A to 11C), m×n variable resistance elements R₁₁ to Rₘₙ (here, R₁₁, R₁₂, R₁₃, R₂₁, R₂₂, and R₂₃), and DC power supplies S₁₁ to Sₘₙ (here, S₁₁, S₁₂, S₁₃, S₂₁, S₂₂, and S₂₃).

Note that this neural network is also called a synapse element or a synapse device. Furthermore, here, each of the m×n variable resistance elements 1 is denoted by the reference signs R₁₁ to Rₘₙ (here, R₁₁, R₁₂, R₁₃, R₂₁, R₂₂, and R₂₃).

Here, when a voltage Vᵢ (1≤i≤m) is input from each of the input wires 10A and 10B, a response current Iⱼ (1≤j≤n) is output from each of the output wires 11A to 11C.

Iⱼ is expressed as follows.

$${I}_{j} = {\sum }_{i = 1}^{m} {V}_{i} {R}_{i , j}^{- 1} \qquad [ Math . 1 ]$$

Iⱼ can be tuned by changing a resistance value Rᵢⱼ (corresponding to a weight value when machine learning is performed) of each of the variable resistance elements R₁₁ to Rₘₙ (here, R₁₁, R₁₂, R₁₃, R₂₁, R₂₂, and R₂₃).

That is, for example, by applying a voltage to each of the variable resistance elements R₁₁ to Rₘₙ (here, R₁₁, R₁₂, R₁₃, R₂₁, R₂₂, and R₂₃) by DC power supplies S₁₁ to Sₘₙ (here, S₁₁, S₁₂, S₁₃, S₂₁, S₂₂, and S₂₃) to change a resistance value of each of the variable resistance elements R₁₁ to Rₘₙ (here, R₁₁, R₁₂, R₁₃, R₂₁, R₂₂, and R₂₃), a response current Iⱼ output from each of the output wires 11A to 11C can be changed.

Therefore, the neural network 9 including the variable resistance element 1 described above functions as a storage device.

In this case, the input wire 10 and the output wire 11 connected to the variable resistance element 1 function as a read circuit 12 for reading out a resistance value (weight value; memory value; data; information) from the variable resistance element 1.

Furthermore, a circuit including the DC power supplies S₁₁ to Sₘₙ (here, S₁₁, S₁₂, S₁₃, S₂₁, S₂₂, and S₂₃) connected to the variable resistance element 1 functions as a write circuit 13 for writing a resistance value (weight value; memory value; data; information) in the variable resistance element 1.

Therefore, the storage device 9 includes the variable resistance element 1 having such a configuration as described above, the write circuit 13 connected to the variable resistance element 1 for writing information in the variable resistance element 1, and the read circuit 12 connected to the variable resistance element 1 for reading out information from the variable resistance element 1.

By the way, a reason why the above-described configuration is adopted is as follows.

Deep learning is a machine learning method using a multilayer neural network, and is currently applied to fields such as image recognition and voice recognition.

The “neural network” mentioned here indicates a network formed by a synaptic connection of an artificial neuron having a role of data input/output.

Machine learning using the neural network involves a process of making actual output data closer to correct output data by changing the strength of each synaptic connection using teacher data (combination of input data and correct output data).

Then, the strength of the synaptic connection is associated with a weight value w when each element of input data is reflected in output data.

Through this process, a machine itself can make judgement for a large amount of new input data and predict output data.

In order to perform association with the weight value in a computer, there is a method for storing the weight value in a memory.

However, the weight value is read out every time, resulting in a decrease in processing speed and an increase in power consumption.

Therefore, a new device that can perform machine learning with low power consumption and a semiconductor chip using the device are needed.

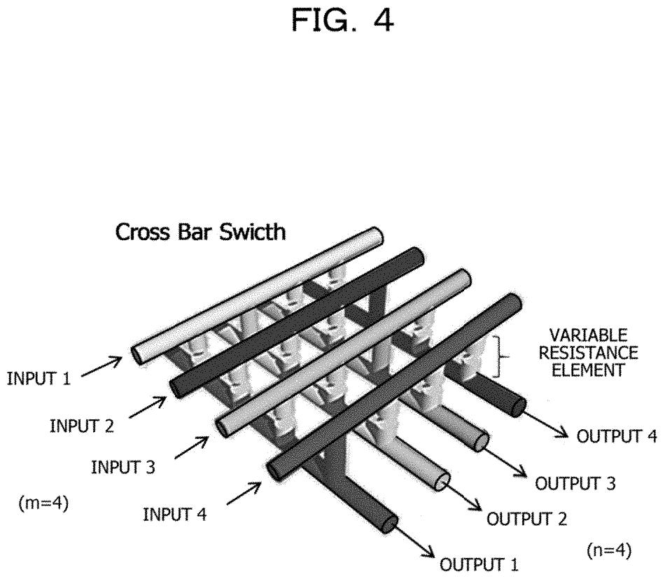

Therefore, for example, as illustrated in FIG. 4, a device (synapse device) imitating a neural network with a crossbar structure has been proposed.

This device includes a nanowire group (m input wires; here m=4) on an input side, a nanowire group (n output wires; here n=4) on an output side, and m×n variable resistance elements disposed between the respective input wires and the respective output wires.

This variable resistance element corresponds to the synaptic connection in the neural network.

That is, for example, the weight value w can be stored using a resistance value R of the variable resistance element. In this case, one w corresponds to one R.

Actually, in a case where a voltage Vᵢₙₚᵤₜ is input to an input wire, the magnitude of a resistance value R is reflected on an output response current Iₒᵤₜₚᵤₜ (see the following formula).

Iₒᵤₜₚᵤₜ=Vᵢₙₚᵤₜ/R

This variable resistance element needs to be nonvolatile in order to store a weight value.

Examples of the nonvolatile resistance memory include magnetoresistive random access memory (MRAM) using magnetism, phase change random access memory (PCRAM) using a crystalline state, and resistive random access memory (ReRAM) using redox and the like.

In a case where the number of weight values that can be handled by such a variable resistance element is, for example, a multi-value including “0”, “1”, “2”, . . . , more accurate prediction is possible with the same size synapse device than in a case where the number of weight values is two including “0” and “1”. Furthermore, similarly, machine learning with the same accuracy can be performed with a smaller size synapse device.

However, the above-described MRAM can take only two values because utilizing magnetic equilibrium and antiequilibrium. Furthermore, the above-described ReRAM uses two states of an oxide state and a metal state, and therefore it is difficult for the ReRAM to maintain an intermediate state therebetween. Moreover, the above-described PCRAM also utilizes a crystalline state and an amorphous state, and therefore it is difficult for the PCRAM to maintain an intermediate state therebetween.

Therefore, for example, a positive electrode material used in a lithium ion battery or the like has attracted attention as a material (memory material) that can achieve a multi-value.

This is because the positive electrode material has a property that the amount of lithium changes reversibly depending on a charged state, and a resistance value changes continuously according to the change in the amount of lithium.

For example, Non-Patent Document 1 describes an example in which LiₓCoO₂ is used as a material of a variable resistance layer.

In such a variable resistance element, in order to control the amount of lithium in the variable resistance layer, an ion conductive layer and an ion occluding/releasing layer are disposed in addition to the variable resistance layer.

The combination of the variable resistance layer, the ion conductive layer, and the ion occluding/releasing layer can be regarded as an “all-solid-state battery”, and can be associated with a positive electrode active material layer, a solid electrolyte layer, and a negative electrode active material layer, respectively.

In this case, a resistance value (weight value) of the variable resistance layer can be changed by applying electric energy Eₐₚₚ between the variable resistance layer and the ion occluding/releasing layer to change a lithium ion concentration in the variable resistance layer.

The electric energy Eₐₚₚ can be expressed by the following formula.

Eₐₚₚ=VₐₚₚIₐₚₚtₐₚₚ

Here, Vₐₚₚ represents an application voltage, Iₐₚₚ represents an application current, and tₐₚₚ represents an application time. Vₐₚₚ can be expressed by the following formula using an open circuit voltage V_{battery} of this all-solid-state battery and an overvoltage Vₒᵥₑᵣₚₒₜₑₙₜᵢₐₗ that affects conduction speed in the ion conductive layer.

Vₐₚₚ=V_{battery}+Vₒᵥₑᵣₚₒₜₑₙₜᵢₐₗ

However, it has been found that if materials used for the variable resistance layer and the ion occluding/releasing layer are not properly selected, V_{battery} is large, voltage Vₐₚₚ applied at the time of writing is large, and electric energy required at the time of writing is large.

For example, in a case of the combination illustrated in Non-Patent Document 1 (variable resistance layer: LiCoO₂, ion occluding/releasing layer: Si), V_{battery}≈3.5 V is satisfied. Therefore, in order to change a resistance value of the variable resistance layer, it is needed to apply electric energy with Vₐₚₚ of about 3.5 V to about 3.6 V (even if Vₒᵥₑᵣₚₒₜₑₙₜᵢₐₗ is less than 0.1 V).

As described above, in order to rewrite a resistance value of the variable resistance layer, it is needed to apply a voltage comparable to a voltage of the all-solid-state battery. Therefore, in order to reduce a necessary voltage, it is needed to reduce a voltage of the all-solid-state battery.

Then, Vₐₚₚ required for writing (rewriting) depends on a material of a variable resistance layer and an ion occluding/releasing layer to be applied.

That is, for example, V_{battery} and Vₐₚₚ can be reduced by appropriately selecting the variable resistance layer and the ion occluding/releasing layer.

This reduces energy Eₐₚₚ required for writing (rewriting) a weight value w corresponding to a resistance value, and further contributes to reducing power required for performing machine learning.

Therefore, in order to achieve a device that can reduce electric energy required for writing a resistance value (weight value), the above-described configuration is adopted.

Therefore, the variable resistance element, the method for manufacturing the same, and the storage device according to the present embodiment may reduce a voltage applied at the time of writing, and may reduce electric energy required at the time of writing.

That is, for example, with such a configuration of the variable resistance element 1 as described above, a potential difference (corresponding to V_{battery}) between the variable resistance layer 3 and the ion occluding/releasing layer 5 may be approximately 0 V. Therefore, electric energy consumed by writing (rewriting) a resistance value (weight value) may be significantly reduced.

For example, the variable resistance element 1 was manufactured as described below, and its effect was confirmed. As a result, in a case where Vₒᵥₑᵣₚₒₜₑₙₜᵢₐₗ was less than 0.1 V, it was confirmed that electric energy required for writing (rewriting) a resistance value (weight value) could be reduced to, for example, about 3% or less as compared with that described in Non-Patent Document 1.

Furthermore, in the present variable resistance element 1, Vₒᵥₑᵣₚₒₜₑₙₜᵢₐₗ≥0.1 V may be satisfied. The larger the Vₒᵥₑᵣₚₒₜₑₙₜᵢₐₗ, the better an ion moving speed in the ion conductive layer and the higher the ion moving speed in the ion conductive layer. Therefore, time required for writing (rewriting) a resistance value (weight value) can be largely reduced.

First as a first specific example, the variable resistance element 1 using a material represented by Li₄₊ₓTi₅O₂ (0≤x≤3) for the variable resistance layer 3 and the ion occluding/releasing layer 5 was manufactured as follows (see, for example, FIG. 1), and its effect was confirmed.

That is, for example, first, on the Si substrate (SiO₂/Si substrate) 2 having a SiO₂ film, a Pt electrode (for example, having a film thickness of about 50 nm) as the first electrode 6 and the second electrode 7, the variable resistance layer 3 having a composition represented by Li₄Ti₅O₁₂ (for example, having a thickness of about 100 nm), the ion conductive layer 4 having a composition represented by LiPON (for example, having a thickness of about 500 nm), and the ion occluding/releasing layer 5 having a composition represented by Li₄Ti₅O₁₂ (having a thickness of about 100 nm) were formed in this order.

Next, metallic lithium was deposited on the ion occluding/releasing layer 5 having a composition represented by Li₄Ti₅O₁₂ by a vapor deposition method.

Here, an equivalent ratio of the amount of metallic lithium to the amount of Li₄Ti₅O₁₂ was three. At this point, as illustrated in the following formula, the ion occluding/releasing layer 5 has reacted with the metallic lithium, and the ion occluding/releasing layer 5 has a composition represented by Li₇Ti₅O₁₂.

Li₄Ti₅O₁₂+3Li→Li₇Ti₅O₁₂

Then, a Pt electrode as the third electrode 8 was formed on the ion occluding/releasing layer 5 having a composition represented by Li₇Ti₅O₁₂.

In this way, the variable resistance element 1 was manufactured (see, for example, FIG. 1).

Next, the effect of the variable resistance element 1 thus manufactured was confirmed.

Here, a voltage of, for example, less than about 0.1 V was applied between the second electrode 7 and the third electrode 8, which are a pair of write electrodes, and a value of x of Li₄₊ₓTi₅O₁₂ constituting the variable resistance layer 3 was changed to three states of about 1.3, about 1.5, and about 1.7. In each of the states, a voltage of, for example, about 10 mV was applied between the first electrode 6 and the second electrode 7, which are a pair of read electrodes. A value of a current flowing according to the application of the voltage was measured.

That is, for example, first, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of Li₄₊ₓTi₅O₁₂ constituting the variable resistance layer 3 was changed to about 1.3 (x=1.3). In this state, a voltage of, for example, about 10 mV was applied from the first electrode 6, which is an input electrode, and a current value I_{x=1.3} observed on a side of the second electrode 7, which is an output electrode, was measured. As a result, the current value I_{x=1.3} was about 0.52 μA.

Next, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of Li₄₊ₓTi₅O₁₂ constituting the variable resistance layer 3 was changed to about 1.5 (x=1.5). In this state, a voltage of, for example, about 10 mV was applied from the first electrode 6, which is an input electrode, and a current value I_{x=1.5} observed on a side of the second electrode 7, which is an output electrode, was measured. As a result, the current value I_{x=1.5} was about 0.60 μA.

Next, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of Li₄₊ₓTi₅O₁₂ constituting the variable resistance layer 3 was changed to about 1.7 (x=1.7). In this state, a voltage of, for example, about 10 mV was applied from the first electrode 6, which is an input electrode, and a current value I_{x=1.7} observed on a side of the second electrode 7, which is an output electrode, was measured. As a result, the current value I_{x=1.7} was about 0.67 μA.

As described above, in the variable resistance element 1 manufactured as described above, only by applying a voltage of, for example, less than about 0.1 V between the second electrode 7 and the third electrode 8, which are a pair of write electrodes, a value of x of Li₄₊ₓTi₅O₁₂ constituting the variable resistance layer 3 could be changed to three states of about 1.3, about 1.5, and about 1.7.

Then, current values I_{x=1.3}, I_{x=1.5}, and I_{x=1.7} observed in states where a value of x in the variable resistance layer 3 having a composition represented by Li₄₊ₓTi₅O₁₂ was changed to x=1.3, x=1.5, and x=1.7, respectively, were measured. As a result, the current values I_{x=1.3}, I_{x=1.5}, and I_{x=1.7} were about 0.52 μA, about 0.60 μA, and about 0.67 μA, respectively, and a significant difference was observed.

This is because resistance values R_{x=1.3}, R_{x=1.5}, and R_{x=1.7} of the variable resistance layer 3 in a case where x=1.3, x=1.5, and x=1.7 are satisfied, respectively, have different values. This makes it possible to associate different weight values w with the respective states.

Then, since a voltage required for changing a state among x=1.3, x=1.5, and x=1.7 is less than about 0.1 V, it was confirmed that electric energy required for writing (rewriting) a resistance value (weight value) could be reduced to, for example, about 3% or less as compared with that described in Non-Patent Document 1.

In the above first specific example, even when the voltage applied between the second electrode 7 and the third electrode 8 was 0.1 V or more (for example, 3.0 V), a resistance value (weight value) could be written (rewritten) similarly. In a case where the application voltage was 3.0 V, time required for writing (rewriting) a resistance value (weight value) could be shortened to about 1/20 as compared with that in a case where the application voltage was less than 0.1 V.

Next as a second specific example, the variable resistance element 1 using a material represented by ZnₓMnO₂ (0≤x≤0.5) for the variable resistance layer 3 and the ion occluding/releasing layer 5 was manufactured as follows, and its effect was confirmed.

That is, for example, first, on the Si substrate (SiO₂/Si substrate) 2 having a SiO₂ film, a Pt electrode (for example, having a film thickness of about 50 nm) as the first electrode 6 and the second electrode 7, the variable resistance layer 3 having a composition represented by MnO₂ (for example, having a thickness of about 100 nm), the ion conductive layer 4 having a composition represented by ZnZr₄(PO₄)₆ (for example, having a thickness of about 200 nm), and the ion occluding/releasing layer 5 having a composition represented by MnO₂ (having a thickness of about 100 nm) were formed in this order.

Next, metallic zinc was deposited on the ion occluding/releasing layer 5 having a composition represented by MnO₂ by a vapor deposition method.

Here, an equivalent ratio of the amount of metallic zinc to the amount of MnO₂ was 0.5. Then, the resulting product was placed in an environment of about 40° C. to about 60° C. After a while, the ion occluding/releasing layer 5 reacted with the metallic zinc as illustrated in the following formula, and the ion occluding/releasing layer 5 had a composition represented by ZnₓMnO₂ (x=0.5), in other words, Zn_{0.5}MnO₂.

MnO₂+0.5Zn→Zn_{0.5}MnO₂

Then, a Pt electrode as the third electrode 8 was formed on the ion occluding/releasing layer 5 having a composition represented by Zn_{0.5}MnO₂.

In this way, the variable resistance element 1 was manufactured.

Next, the effect of the variable resistance element 1 thus manufactured was confirmed.

Here, a voltage of, for example, less than about 0.1 V was applied between the second electrode 7 and the third electrode 8, which are a pair of write electrodes, and a value of x of ZnₓMnO₂ constituting the variable resistance layer 3 was changed to three states of about 0.2, about 0.3, and about 0.4. In each of the states, a voltage of, for example, about 10 mV was applied between the first electrode 6 and the second electrode 7, which are a pair of read electrodes. A value of a current flowing according to the application of the voltage was measured.

That is, for example, first, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of ZnₓMnO₂ constituting the variable resistance layer 3 was changed to about 0.2 (x=0.2). In this state, a voltage of, for example, about 10 mV was applied from the first electrode 6, which is an input electrode, and a current value I_{x=0.2} observed on a side of the second electrode 7, which is an output electrode, was measured.

Next, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of ZnₓMnO₂ constituting the variable resistance layer 3 was changed to about 0.3 (x=0.3). In this state, a voltage of, for example, about 10 mV was applied from the first electrode 6, which is an input electrode, and a current value I_{x=0.3} observed on a side of the second electrode 7, which is an output electrode, was measured.

Next, a voltage of, for example, less than about 0.1 V was applied between the second electrode 7 and the third electrode 8, which are a pair of write electrodes, to impart electric energy to the structure obtained by stacking the variable resistance layer 3, the ion conductive layer 4, and the ion occluding/releasing layer 5. A value of x of ZnₓMnO₂ constituting the variable resistance layer 3 was changed to about 0.4 (x=0.4). In this state, a voltage of, for example, about 10 mV was applied from the first electrode 6, which is an input electrode, and a current value I_{x=0.4} observed on a side of the second electrode 7, which is an output electrode, was measured.

As described above, in the variable resistance element 1 manufactured as described above, only by applying a voltage of, for example, less than about 0.1 V between the second electrode 7 and the third electrode 8, which are a pair of write electrodes, a value of x of ZnₓMnO₂ constituting the variable resistance layer 3 could be changed to three states of about 0.2, about 0.3, and about 0.4.

Then, current values I_{x=1.3}, I_{x=1.5}, and I_{x=1.7} observed in states where a value of x in the variable resistance layer 3 having a composition represented by ZnₓMnO₂ was changed to x=0.2, x=0.3, and x=0.4, respectively, were measured. As a result, a significant difference was observed.

This is because resistance values R_{x=0.2}, R_{x=0.3}, and R_{x=0.4} of the variable resistance layer 3 in a case where x=0.2, x=0.3, and x=0.4 are satisfied, respectively, have different values. This makes it possible to associate different weight values w with the respective states.

Then, since a voltage required for changing a state among x=0.2, x=0.3, and x=0.4 is less than about 0.1 V, it was confirmed that electric energy required for writing (rewriting) a resistance value (weight value) could be reduced to, for example, about 3% or less as compared with that described in Non-Patent Document 1.

In the above second specific example, even when the voltage applied between the second electrode 7 and the third electrode 8 was 0.1 V or more (for example, 2.0 V), a resistance value (weight value) could be written (rewritten) similarly. In a case where the application voltage was 2.0 V, time required for writing (rewriting) a resistance value (weight value) could be shortened to about 1/15 as compared with that in a case where the application voltage was less than 0.1 V.

Next, using the variable resistance element 1 (see, for example, FIG. 1) manufactured as described above, the neural network 9 was manufactured (see, for example, FIG. 3), and its effect was confirmed.

Here, first, using the variable resistance element 1 of the above-described first specific example, in other words, for example, using the variable resistance element 1 manufactured using a material represented by Li₄₊ₓTi₅O₁₂ for the variable resistance layer 3 and the ion occluding/releasing layer 5 (see, for example, FIG. 1), the neural network 9 inducing two input terminals (input wires) 10A and 10B, three output terminals (output wires) 11A to 11C, six variable resistance elements R₁₁, R₁₂, R₁₃, R₂₁, R₂₂, and R₂₃, and six DC power supplies S₁₁, S₁₂, S₁₃, S₂₁, S₂₂, and S₂₃ was manufactured (see, for example, FIG. 3).

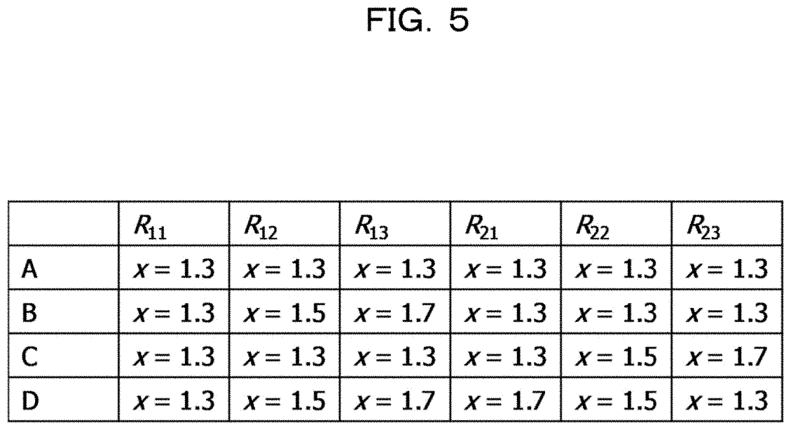

Then, a value of x of Li_{4+X}Ti₅O₁₂ constituting the variable resistance layer 3 included in each of the six variable resistance elements R₁₁, R₁₂, R₁₃, R₂₁, R₂₂, and R₂₃ was adjusted, as illustrated in FIG. 5, so as to be a combination indicated by each of A to D by the six DC power supplies S₁₁, S₁₂, S₁₃, S₂₁, S₂₂, and S₂₃, respectively. Currents (output currents) I₁, I₂, and I₃ output from the three output terminals 11A to 11C for voltages (input voltages) V and V₂ applied to the two input terminals 10A and 10B were measured. Note that here, values of V₁ and V₂ were fixed at 10 mV and 15 mV, respectively.

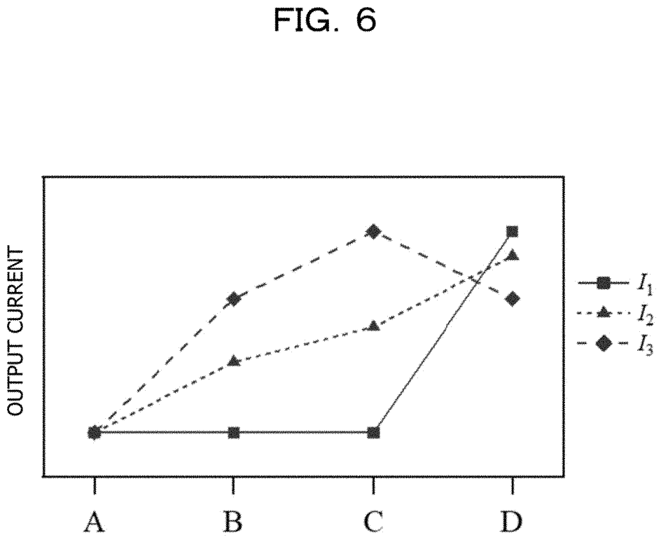

As a result, the output currents I₁, I₂, and I₃ are as illustrated in FIG. 6 for each of the combinations A to D.

Next, using the variable resistance element 1 of the above-described second specific example, in other words, for example, using the variable resistance element 1 manufactured using a material represented by ZnₓMnO₂ for the variable resistance layer 3 and the ion occluding/releasing layer 5 (see, for example, FIG. 1), the neural network 9 including two input terminals (input wires) 10A and 10B, three output terminals (output wires) 11A to 11C, six variable resistance elements R₁₁, R₁₂, R₁₃, R₂₁, R₂₂, and R₂₃, and six DC power supplies S₁₁, S₁₂, S₁₃, S₂₁, S₂₂, and S₂₃ was manufactured similarly (see, for example, FIG. 3).

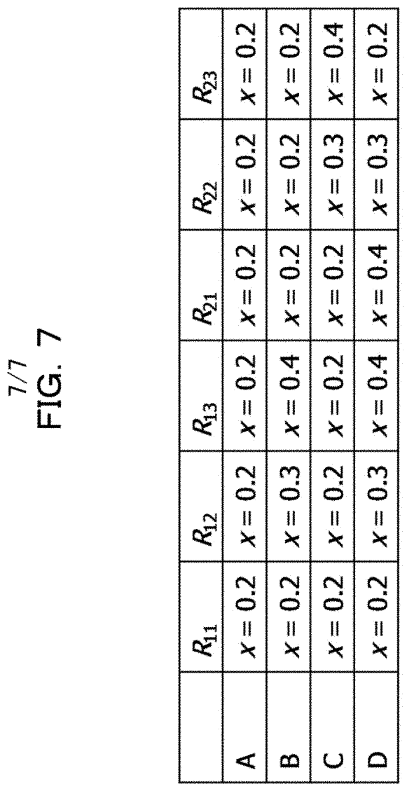

Then, a value of x of ZnₓMnO₂ constituting the variable resistance layer 3 included in each of the six variable resistance elements R₁₁, R₁₂, R₁₃, R₂₁, R₂₂, and R₂₃ was adjusted, as illustrated in FIG. 7, so as to be a combination indicated by each of A to D by the six DC power supplies S₁₁, S₁₂, S₁₃, S₂₁, S₂₂, and S₂₃, respectively. Currents (output currents) I₁, I₂, and I₃ output from the three output terminals 11A to 11C for voltages (input voltages) V₁ and V₂ applied to the two input terminals 10A and 10B were measured. Note that here, values of V₁ and V₂ were fixed at 10 mV and 15 mV, respectively.

As a result, the output currents I₁, I₂, and I₃ with each of the combinations A to D had almost the same result as those in FIG. 6 described above.

As described above, it was confirmed that the neural network 9 using the variable resistance element 1 manufactured as described above functioned as a multi-valued memory. Furthermore, it was confirmed that using an effect of the multi-valued memory, more diverse output currents could be detected with a smaller number of elements as compared with a memory that can take only two values.

Note that the embodiment is not limited to the configuration described in the embodiment described above, and various modifications may be made to the embodiment without departing from the scope of the embodiment, and appropriate combination can be made.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A variable resistance element comprising:
a variable resistance layer that is able to occlude and release at least one type of ions, and changes a resistance of the variable resistance layer according to an amount of the at least one type of ions;
an ion occluding/releasing layer that is able to occlude and release the at least one type of ions; and
an ion conductive layer that conducts the at least one type of ions between the variable resistance layer and the ion occluding/releasing layer, wherein
the variable resistance layer and the ion occluding/releasing layer are made of the same constituent elements.

2. The variable resistance element according to claim 1, wherein the variable resistance layer and the ion occluding/releasing layer have the same composition ratio of elements other than an element to be used as the at least one type of ions.

3. The variable resistance element according to claim 2, wherein the variable resistance layer and the ion occluding/releasing layer have different composition ratios of the element to be used as the at least one type of ions.

4. The variable resistance element according to claim 2, wherein the variable resistance layer and the ion occluding/releasing layer have the same composition ratio of the element to be used as the at least one type of ions.

5. The variable resistance element according to claim 1, wherein the at least one type of ions are any one of Li ions, Zn ions, Na ions, K ions, Mg ions, Al ions, Ag ions, and Cu ions.

6. The variable resistance element according to claim 1, wherein the at least one type of ions are Li ions.

7. The variable resistance element according to claim 6, wherein the variable resistance layer and the ion occluding/releasing layer each have a composition represented by Li₄₊ₓTi₅O₁₂ (0≤x≤3).

8. The variable resistance element according to claim 7, wherein at least one of the variable resistance layer and the ion occluding/releasing layer is adjusted such that a value of x satisfies 0≤x≤3.

9. The variable resistance element according to claim 1, wherein the at least one type of ions are Zn ions.

10. The variable resistance element according to claim 9, wherein the variable resistance layer and the ion occluding/releasing layer each have a composition represented by ZnₓMnO₂ (0≤x≤0.5).

11. The variable resistance element according to claim 10, wherein at least one of the variable resistance layer and the on occluding/releasing layer is adjusted such that a value of x satisfies 0<x≤0.5.

12. A storage device comprising:
a variable resistance element;
a write circuit that is connected to the variable resistance element and writes information in the variable resistance element; and
a read circuit that is connected to the variable resistance element and reads out information from the variable resistance element, wherein
the variable resistance element includes:
a variable resistance layer that is able to occlude and release at least one type of ions, and changes a resistance of the variable resistance according to an amount of the at least one type of ions;
an ion occluding/releasing layer that is able to occlude and release the at least one type of ions; and
an ion conductive layer that conducts the at least one type of ions between the variable resistance layer and the ion occluding/releasing layer, and
the variable resistance layer and the ion occluding/releasing layer are made of the same constituent elements.

13. The storage device according to claim 12, wherein the variable resistance layer and the ion occluding/releasing layer have the same composition ratio of elements other than an element to be used as the at least one type of ions.

14. The storage device according to claim 13, wherein the variable resistance layer and the ion occluding/releasing layer have different composition ratios of the element to be used as the at least one type of ions.

15. The storage device according to claim 13, wherein the variable resistance layer and the ion occluding/releasing layer have the same composition ratio of the element to be used as the at least one type of ions.

16. The storage device according to claim 12, wherein the at least one type of ions are any one of Li ions, Zn ions, Na ions, K ions, Mg ions, Al ions, Ag ions, and Cu ions.

17. The storage device according to claim 12, wherein
the at least one type of ions are Li ions, and
the variable resistance layer and the ion occluding/releasing layer each have a composition represented by Li₄₊ₓTi₅O₁₂ (0≤x≤3).

18. The storage device according to claim 12, wherein
the at least one type of ions are Zn ions, and
the variable resistance layer and the ion occluding/releasing layer each have a composition represented by ZnₓMnO₂ (0≤x≤0.5).

19. A method for manufacturing a variable resistance element, the method comprising:
forming a variable resistance layer that is able to occlude and release at least one type of ions, and changes a resistance of the variable resistance layer according to an amount of the at least one type of ions;
forming an ion occluding/releasing layer that is able to occlude and release the at least one type of ions; and
forming an ion conductive layer that conducts the at least one type of ions between the variable resistance layer and the ion occluding/releasing layer, wherein
in the forming the variable resistance layer and the forming the ion occluding/releasing layer, the variable resistance layer and the ion occluding/releasing layer made of the same constituent elements are formed, respectively.
